(19) United States
(12) Patent Application Publication
(10) Pub. No.: US 2023/0142690 A1
(43) Pub. Date: May 11, 2023

(54) BATTERY CELL TEMPERATURE ESTIMATION USING BOTH CELL IMPEDANCE ESTIMATION AND MODULE TEMPERATURE SENSOR MEASUREMENT

(71) Applicant: GM GLOBAL TECHNOLOGY OPERATIONS LLC, Detroit, MI (US)

(72) Inventors: Steven E. MULDOON, Royal Oak, MI (US); Yue-Yun Wang, Troy, MI (US); Lei Hao, Troy, MI (US)

(21) Appl. No.: 17/519,989

(22) Filed: Nov. 5, 2021

(51) Int. Cl. H01M 10/48; G01R 31/367; G01R 31/374; G01R 31/3835; G01R 31/389

(52) U.S. Cl. CPC H01M 10/486; G01R 31/367; G01R 31/374; G01R 31/3835; G01R 31/389; H01M 10/482

(57) ABSTRACT

A monitoring system for a battery system includes a battery system including a battery pack. The battery pack includes M battery modules, where M is an integer greater than zero. Each of the M battery modules includes C battery cells, where C is an integer greater than one. T temperature sensors configured to generate sensed temperatures of the M battery modules, where T is greater than or equal to M and less than M times C. A battery management module configured to perform battery impedance measurements on the C battery cells of the M battery modules; generate estimated temperatures for each of the C battery cells of the M battery modules based on the battery impedance measurements; and selectively detect at least one of the C battery cells having a cell outlier temperature based on the estimated temperatures of the C battery cells.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to battery systems for vehicles and more particularly to temperature monitoring systems for battery systems of vehicles.

Electric vehicles such as battery electric vehicle (BEVs), fuel cell vehicles and hybrid vehicles include one or more battery packs each including one or more battery modules. Each of the battery modules includes one or more battery cells. A power control system is used to control charging and/or discharging of the battery packs during operation. During driving, one or more electric machines of the EV operate as a motor and receive power from the battery system to provide propulsion for the vehicle. During braking/regeneration, power is returned to the battery system by the electric machine operating as a generator.

During operation of the EV, the battery cells may experience heating due to charging and discharging. Battery life may be adversely impacted by operation for extended periods at higher temperatures. As a result, battery cooling systems may be used to maintain the temperature of the battery system within a predetermined temperature range. Various faults that may occur in the battery system may cause excessive heating of the battery cells in the battery system beyond what the battery cooling system can control.

### SUMMARY

A monitoring system for a battery system includes a battery system including a battery pack. The battery pack includes M battery modules, where M is an integer greater than zero. Each of the M battery modules includes C battery cells, where C is an integer greater than one. T temperature sensors configured to generate sensed temperatures of the M battery modules, where T is greater than or equal to M and less than M times C. A battery management module configured to perform battery impedance measurements on the C battery cells of the M battery modules; generate estimated temperatures for each of the C battery cells of the M battery modules based on the battery impedance measurements; and selectively detect at least one of the C battery cells having a cell outlier temperature based on the estimated temperatures of the C battery cells.

In other features, the battery management module is further configured to use the estimated temperatures of the C battery cells for the M battery modules and the sensed temperatures to selectively detect at least one of: a fault in the T temperature sensors; and one of the M battery modules having a module outlier temperature.

In other features, the battery management module is further configured to determine cell temperature residuals for each of the C battery cells of the M battery modules based on the battery impedance measurements for the C battery cells of the M battery modules; calculate a first temperature standard deviation for each of the M battery modules based on the cell temperature residuals; and selectively identify one of the C battery cells having the cell outlier temperature by comparing the cell temperature residuals of the C battery cells to the first temperature standard deviation for corresponding ones of the M battery modules.

In other features, the cell temperature residuals are calculated based on a difference between each of the estimated temperatures of the C battery cells for the M battery modules and an average of the estimated temperatures of the C battery cells for corresponding ones of the M battery modules.

In other features, the battery management module includes M generating and sensing modules for the M battery modules, respectively, wherein each of the M generating and sensing modules includes a current generator configured to generate current excitation pulses that are output to the C battery cells; and C voltage sensors configured to generate measured voltages for the C battery cells in response to the current excitation pulses. The monitoring system further includes an impedance measurement module configured to cause the current generator to generate the current excitation pulses, receive the measured voltages, and estimate cell impedances of the C battery cells based on the current excitation pulses and the measured voltages; and a temperature estimation module configured to estimate C temperatures of the C battery cells based on the estimated cell impedances.

In other features, the temperature estimation module is further configured to generate the estimated temperatures of the C battery cells, further based on a state of charge (SOC) of the battery system and a frequency of the current excitation pulses. M is greater than one and wherein the battery management module is further configured to determine module residuals for each of the M battery modules; calculate a standard deviation for the M battery modules based on the module residuals; and selectively identify one of the M modules having an outlier module temperature by comparing the module residuals to the standard deviation.

In other features, the battery management module calculates a first set of averages of the estimated temperatures of the C battery cells for corresponding ones of the M battery modules; the module residuals for the M battery modules are calculated based a difference between a second average based on the first set of averages. The module residuals are based differences between the first set of averages and the second average.

In other features, the battery management module calculates an average based on the sensed temperatures of the M battery modules; and residuals for the M battery modules are calculated based a difference between the sensed temperatures of the M battery modules and the average.

In other features, the battery management module is configured to adjust at least one operating parameter of an electric motor in response to determination that one of the C battery cells in one of the M battery modules has the cell outlier temperature. The at least one operating parameter includes performing a thermal runaway mitigation action in response to the cell outlier temperature being greater than a predetermined temperature threshold. The battery management module is configured switch between thermal control based a corresponding sensed temperature for the one of the M battery modules and the cell outlier temperature of the one of the C battery cells in one of the M battery modules.

A method for monitoring temperatures in a battery system includes generating sensed temperatures of M battery modules each including C battery cells using T temperature sensors. T and M are integers greater than zero and C is an integer greater than one. T is greater than or equal to M and less than M times C. The method includes performing battery impedance measurements on the C battery cells of the M battery modules; generating estimated temperatures for each of the C battery cells of the M battery modules based on the battery impedance measurements; selectively detecting at least one of the C battery cells having a cell outlier temperature based on the estimated temperatures of the C battery cells; and altering at least one operating parameter of the battery system in response to the cell outlier temperature.

In other features, the method includes using the estimated temperatures of the C battery cells for the M battery modules and the sensed temperatures to selectively detect at least one of: a fault in the T temperature sensors; and one of the M battery modules having a module outlier temperature.

In other features, the method includes determining cell temperature residuals for each of the C battery cells of the M battery modules based on the battery impedance measurements for the C battery cells of the M battery modules; calculating a first temperature standard deviation for each of the M battery modules based on the cell temperature residuals; and selectively identifying one of the C battery cells having the cell outlier temperature by comparing the cell temperature residuals of the C battery cells to the first temperature standard deviation for corresponding ones of the M battery modules.

In other features, the method includes calculating the cell temperature residuals based on a difference between each of the estimated temperatures of the C battery cells for the M battery modules and an average of the estimated temperatures of the C battery cells for corresponding ones of the M battery modules.

In other features, the method includes generating current excitation pulses that are output to the C battery cells; and measuring voltages for the C battery cells in response to the current excitation pulses; estimating cell impedances of the C battery cells based on the current excitation pulses and the measured voltages; estimating C temperatures of the C battery cells based on the estimated cell impedances of the C battery cells, a state of charge (SOC) of the battery system and a frequency of the current excitation pulses; determining module temperature residuals for each of the M battery modules; calculating a module temperature standard deviation for the M battery modules based on the module temperature residuals; and selectively identifying one of the M battery modules having an outlier module temperature by comparing the module temperature residuals to the module temperature standard deviation.

A non-transitory computer readable medium includes instructions that, where executed by a processor, are configured to monitor temperatures in a battery system by receiving sensed temperatures of M battery modules each including C battery cells using T temperature sensors, where T and M are integers greater than zero and C is an integer greater than one, and wherein T is greater than or equal to M and less than M times C; and generating battery impedance measurements on the C battery cells of the M battery modules; generating estimated temperatures for each of the C battery cells of the M battery modules based on the battery impedance measurements; selectively detecting at least one of the C battery cells having a cell outlier temperature based on the estimated temperatures of the C battery cells; and altering at least one operating parameter of the battery system in response to the cell outlier temperature.

In other features, the non-transitory computer readable medium further comprises instructions for using the estimated temperatures of the C battery cells for the M battery modules and the sensed temperatures to selectively detect at least one of a fault in one of the T temperature sensors; and one of the M battery modules having a module outlier temperature.

In other features, the non-transitory computer readable medium further comprises instructions for determining cell temperature residuals for each of the C battery cells of the M battery modules based on the battery impedance measurements for the C battery cells of the M battery modules; calculating a first temperature standard deviation for each of the M battery modules based on the cell temperature residuals; and selectively identifying one of the C battery cells having the cell outlier temperature by comparing the cell temperature residuals of the C battery cells to the first temperature standard deviation for corresponding ones of the M battery modules.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of a simplified example of a temperature monitoring system for battery cells of a battery module according to the present disclosure;

FIG. 2 is a graph illustrating an example of a current excitation signal according to the present disclosure;

FIG. 3 is an example of a Nyquist plot including imaginary impedance as a function of real impedance for a battery cell at different temperatures of the battery cell;

FIG. 4 is a functional block diagram of an example of a temperature monitoring system for a battery system including multiple battery modules according to the present disclosure;

FIGS. 5 and 6 are flowcharts of examples of methods for monitoring temperatures of battery cells of a battery module and temperatures of the battery modules according to the present disclosure; and

FIG. 7 is a flowchart of an example of a method for monitoring temperature sensors of the battery modules according to the present disclosure.

In the drawings, reference numbers may be reused to identify similar and/or identical elements.

### DETAILED DESCRIPTION

Due to cost limitations, each battery module generally only has only one sensor (or two temperature sensors to provide redundancy at the module level). However, the number of temperature sensors is fewer than the total number of battery cells in the battery modules. Therefore, the battery management module does not receive temperature information for each individual battery cell in the battery module.

The battery temperature monitoring system according to the present disclosure estimates the temperature of each battery cell using battery impedance measurements. In some examples, the battery impedance measurements include electrochemical impedance spectroscopy (EIS) analysis, although other types of battery impedance measurements can be used. Use of the battery cell temperature estimates based on battery impedance in conjunction with the measured temperature from sensors on the battery module allows improved battery thermal health monitoring and management.

During battery impedance measurement, a small amplitude current excitation signal is supplied at a selected frequency to the battery cells and the corresponding voltage response of the cell is measured. These measurements can be used to measure battery cell impedance and to estimate battery cell temperature. When these measurements are performed at different frequencies, states of charge (SOC) and temperatures, an impedance spectrum of the battery can be obtained.

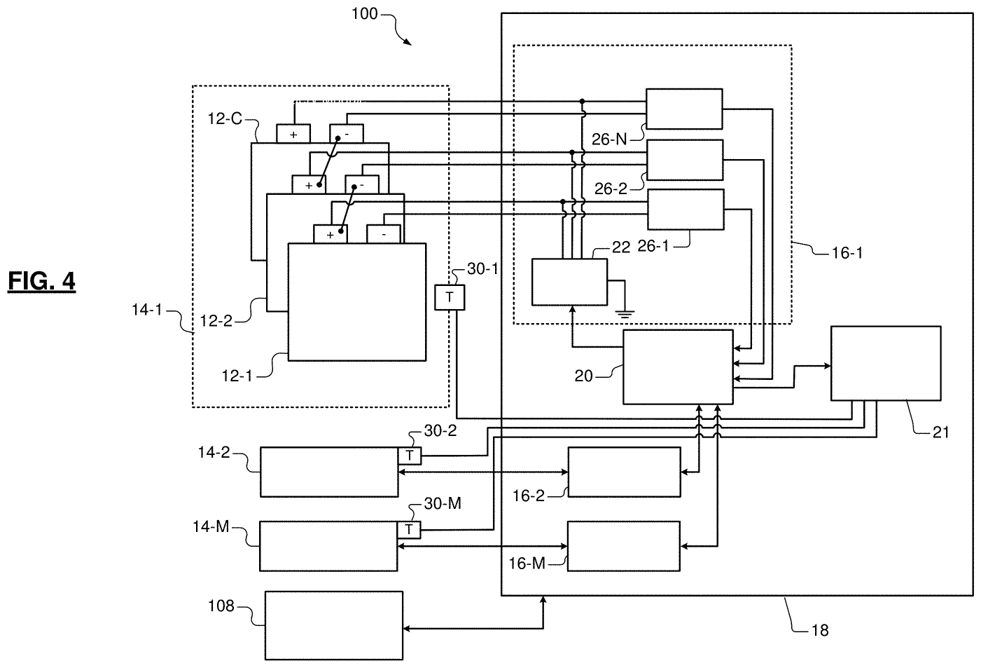

The response results are typically shown graphically with Nyquist plots of the imaginary vs. real impedance (an example of which is shown in FIG. 3) for different frequencies and SOCs. In other words, the internal temperature of the battery is a function of measured impedance of the battery cell, state of charge (SOC) and frequency (Temperature (T)=f(Z,SOC,freq)). With the measured battery cell impedances, battery SOC and frequency, the battery internal temperature can be estimated. In some examples, lookup tables or a mathematical model are used.

Use of battery impedance measurement is scheduled and sampled at various times and modes during vehicle operation. As a result, the battery management module is able to use individual battery cell temperature as input parameter, complementing and/or improving battery state of health (SOH) and/or state of charge (SOC) capabilities.

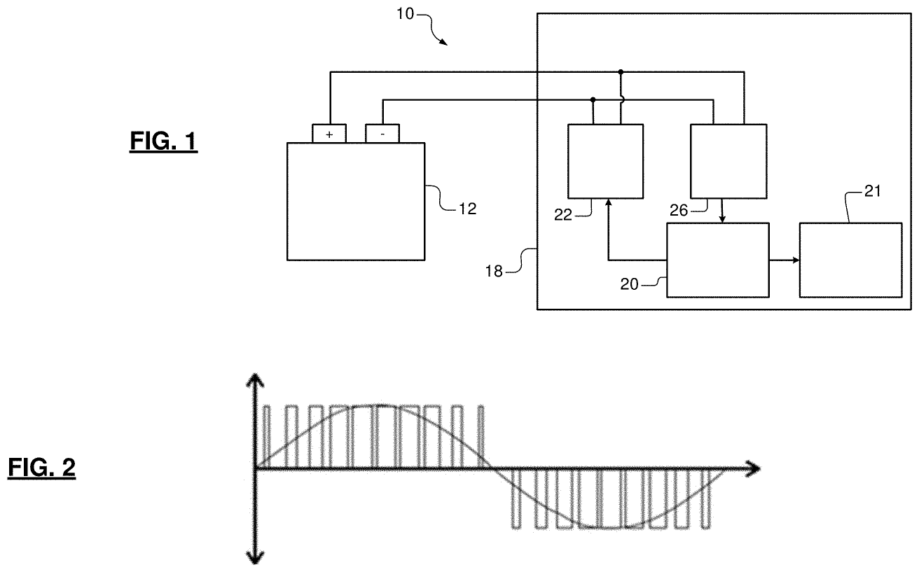

Referring now to FIGS. 1 to 3, measurement of the temperature of individual battery cells in a battery module is shown. In FIG. 1, a battery temperature monitoring system 10 for a battery cell 12 of a battery module is shown. A battery management module 18 includes an impedance measurement module 20, a temperature estimation module 21, a current generator 22, and a voltage sensor 26. The impedance measurement module 20 causes the current generator 22 to selectively generate the current excitation signal at a predetermined frequency and amplitude and the voltage sensor 26 measures the voltage response. The impedance measurement module 20 calculates the battery cell impedances. The temperature estimation module 21 estimates battery cell temperatures based on the battery cell impedances and calculates residual values and standard deviations as will be described further below.

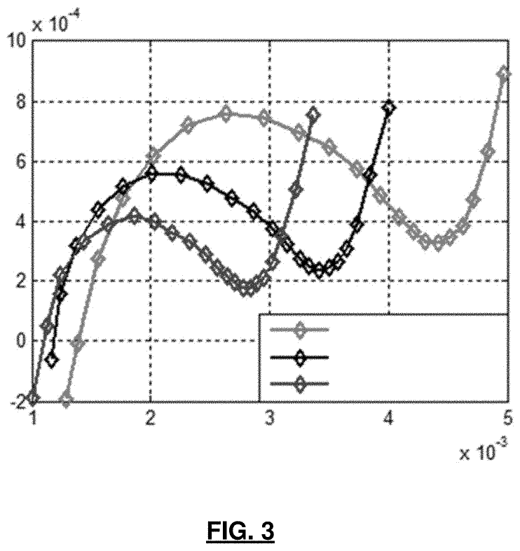

In FIG. 2, an example of a current excitation signal having the predetermined frequency and amplitude is shown. In some examples, the current excitation signal corresponds to a pulse width modulated (PWM) signal. The on-time of positive PWM pulses successively increases and then decreases during a first half of a cycle and then on-time of negative PWM pulses successively increases and then decreases during a second half of a cycle. While a PWM signal is shown, the excitation current or voltage can be generated in other ways.

In FIG. 3, a Nyquist plot includes different battery cell temperature curves as a function of imaginary and real impedance for a battery cell at a particular SOC and frequency. The measured impedance can be compared to the set of temperature curves for the battery cell for a given SOC and frequency. The impedance from the measurement is compared to the set of temperature curves and an estimated temperature is selected. In some examples, interpolation can be used to estimate battery cell temperatures between the set of temperature curves for a given SOC and frequency.

In some examples, each cell in the battery module receives the excitation signal and individual cell voltages are measured by the battery management module (BMS). These impedance-based measurements set the stage for differential analysis of the temperature measurement results between cells, modules and battery packs when under similar environmental and load conditions.

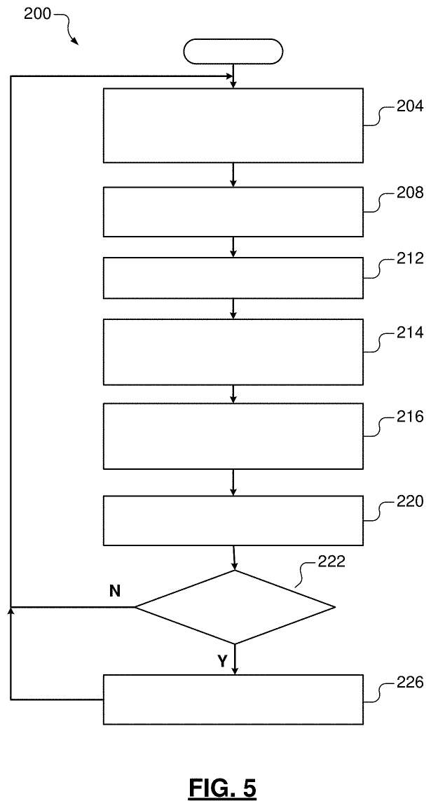

Referring now to FIG. 4, a battery temperature monitoring system 100 for a battery system including M battery modules 14-1, 14-2, . . . , and 14-M (where M is an integer greater than zero) (collectively or individually battery modules 14). Each of the battery modules 14 includes C battery cells (where C is an integer greater than one) (collectively or individually battery cells 12). In some examples, each of the battery modules 14 includes a temperature sensor 30-1, 30-2, . . . , and 30-M (collectively or individually temperature sensors 30). In some examples, T=M. In other examples, T=2M and T<M*C.

The battery management module 18 includes generating and sensing circuits 16-1, 16-2, . . . , and 16-M (collectively or individually voltage and current generators 16). In some examples, the generating and sensing circuits 16 include voltage sensors 26-1, 26-2, . . . , and 26-N and a current generator 22. The impedance measurement module 20 communicates with the voltage sensors 26 and the current generator 22 to initiate the current excitation signal, measure the voltage response, estimate battery cell impedances.

The temperature estimation module 21 estimates temperatures for each battery cell in a respective battery module based on the cell impedances and generates average temperature for each the battery modules. In some examples, the temperature estimation module 21 calculates residuals and standard deviations as will be described further below. In some examples, the calculations are used by a propulsion system control module to alter an operating parameter of the electric motor or other vehicle system based on the calculations.

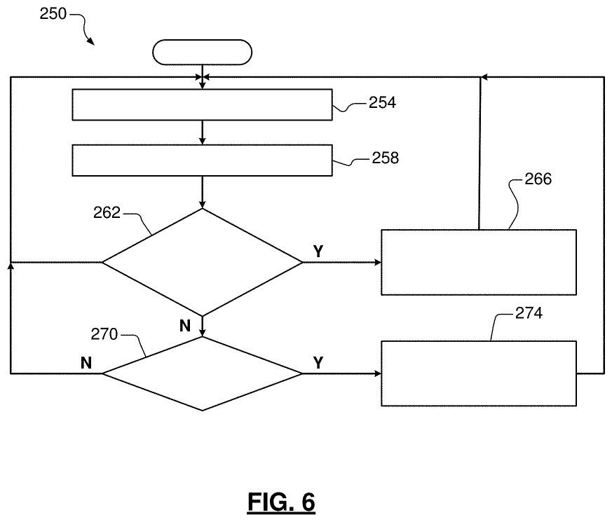

Referring now to FIGS. 5 and 6, methods 200 and 300 for monitoring battery cells of a battery module are shown. At 204, current excitation signals are generated at a predetermined frequency and output to the battery cells in the battery modules. At 208, voltage responses of the battery cells in the battery module are measured. At 212, impedances of the battery cells in the battery module are calculated. At 214, a temperature of battery cells in the battery module is estimated based on the impedances.

At 216, an estimated mean temperature T for the battery cells in the battery module are calculated based on the estimate battery cell temperature of the corresponding battery module. At 220, temperatures of battery cells are compared to the mean temperature T for the battery module. At 222, the method determines whether there are any battery cells with outlier battery temperatures. If 222 is false, the method returns to 204. If 222 is true, a fault is declared and/or one or more operating parameters are adjusted at 226.

In some examples, the mean module temperature is calculated from the estimated cell temperatures for each battery cell (which are determined based on impedance, SOC and frequency as described above). The mean cell temperature is subtracted from the estimated cell temperatures to determine residuals for each battery cell. The standard deviation of the residuals for the battery cells are calculated. In some examples, outlier battery cell temperatures are identified when the residual is greater than or equal to a predetermined threshold. In some examples, the predetermined threshold is k1*the standard deviation, where k1 is a constant. In other examples, a lookup table or mathematical function is used.

A similar approach can be used to identify outlier battery modules. The mean battery module temperature for a battery pack can be calculated based on the battery module temperatures for each battery module. The battery module temperatures for each battery module can be based on the means of the estimated cell temperatures (determined based on the impedance measurements of the battery cells) or the sensed temperatures of the battery modules as sensed by the temperature sensors.

The mean battery module temperature is subtracted from the battery module temperatures to determine module residuals. The standard deviation of the module residuals is calculated. In some examples, the module residuals are compared to a predetermined threshold and outlier battery module temperatures are identified. In some examples, the predetermined threshold equal to k2*the standard deviation, where k2 is a constant. In other examples, a lookup table or mathematical function is used.

In FIG. 6, a method 250 for adjusting operation is shown. At 254, the battery cell temperatures are estimated. At 258, residuals are calculated. At 262, the method determines whether the residual of one battery cell is greater than others in the battery module and the temperature of the battery cell is less than a predetermined temperature T1. In some examples, the predetermined temperature is 45° C.

If 262 is true, the method continues at 266 and the estimated battery temperature of the hottest battery cell is used as a temperature reference for the battery module (rather than the measured temperature from the temperature sensor or another value). In some examples, additional action can be taken such as increasing cooling to the battery module including the battery cell with the outlier temperature to cool the battery module.

If 262 is false, the method continues at 270 and determines whether the estimated temperature of the battery cell is greater than the predetermined temperature T1. In some examples, the predetermined temperature T1 corresponds to a temperature such as 45° C. or another temperature indicative of potential thermal runaway. If 270 is true, the method continues at 274 and performs one or more thermal mitigation actions. An example of a thermal mitigation action includes discharging the battery modules into a load to reduce power stored in the battery.

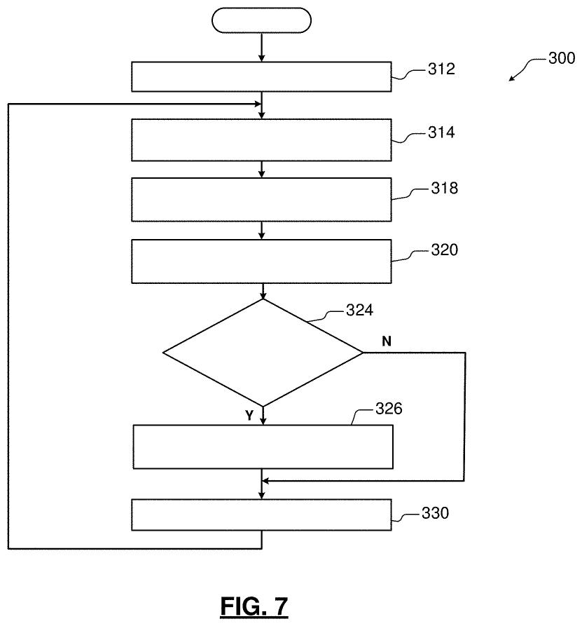

Referring now to FIG. 7, a method 300 for monitoring operation of temperature sensors of the battery modules is shown. At 312, one of the battery modules is selected. At 314, temperatures of battery cells are estimated and an average temperature for the battery module is generated. At 318, the temperature sensor for the battery module is sampled. At 320, a difference between average temp and sensed temperature is generated. At 324, if the absolute value of the difference is greater than a threshold, a fault is set for the temperature sensor at 326. The method continues from 326 or 324 (if false) and selects the next battery module and repeats.

The battery management module provides an on-board system and methodology to monitor and manage battery system thermal health using a combination of battery impedance measurements to provide estimated temperatures for each battery cell and surface temperature measurements from temperature sensors on the battery modules.

The battery management module generates battery impedance measurements for each cell, compares cell temperatures within the battery module to monitor for a potential hot battery cells due to an undesired thermal event, obtains cell temperature estimates, calculates standard deviation from all residuals of the estimate values, and selectively takes action if one or more of the residuals is outside of a predetermined thresholds. If one residual is higher than the others, the outlying cell is experiencing an internal temperature rise that is out of bounds. This early detection can be used as a prognostic indicator.

The battery management module utilizes the estimated temperatures of each battery module and compares these values to the measured temperatures between the battery modules in a battery pack to detect module or sensor faults. The battery management module measures battery impedance-derived cell temperature estimates and calculates the mean estimated temperature for each module. The battery management module calculates the standard deviation from the residuals of the estimate. The battery management module applies an algorithm, function and/or lookup table and determines if a residual is outside of a predetermined limit. If one residual is higher than the others, a temperature sensor may be faulty or the module cooling function for the battery module may be faulty.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “impedance measurement module” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C #, Objective-C, Swift, Haskell, Go, SQL, R, Lisp, Java®, Fortran, Perl, Pascal, Curl, OCaml, Javascript®, HTML5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is:

1. A monitoring system for a battery system, comprising:
a battery system including a battery pack,
wherein the battery pack includes M battery modules, where M is an integer greater than zero,
wherein each of the M battery modules includes C battery cells, where C is an integer greater than one;
T temperature sensors configured to generate sensed temperatures of the M battery modules, where T is greater than or equal to M and less than M times C; and
a battery management module configured to:
perform battery impedance measurements on the C battery cells of the M battery modules;
generate estimated temperatures for each of the C battery cells of the M battery modules based on the battery impedance measurements; and
selectively detect at least one of the C battery cells having a cell outlier temperature based on the estimated temperatures of the C battery cells.

2. The monitoring system of claim 1, wherein the battery management module is further configured to use the estimated temperatures of the C battery cells for the M battery modules and the sensed temperatures to selectively detect at least one of:
a fault in the T temperature sensors; and
one of the M battery modules having a module outlier temperature.

3. The monitoring system of claim 1, wherein the battery management module is further configured to:
determine cell temperature residuals for each of the C battery cells of the M battery modules based on the battery impedance measurements for the C battery cells of the M battery modules;
calculate a first temperature standard deviation for each of the M battery modules based on the cell temperature residuals; and
selectively identify one of the C battery cells having the cell outlier temperature by comparing the cell temperature residuals of the C battery cells to the first temperature standard deviation for corresponding ones of the M battery modules.

4. The monitoring system of claim 3, wherein the cell temperature residuals are calculated based on a difference between each of the estimated temperatures of the C battery cells for the M battery modules and an average of the estimated temperatures of the C battery cells for corresponding ones of the M battery modules.

5. The monitoring system of claim 4, wherein:
the battery management module includes M generating and sensing modules for the M battery modules, respectively, wherein each of the M generating and sensing modules includes:
a current generator configured to generate current excitation pulses that are output to the C battery cells; and
C voltage sensors configured to generate measured voltages for the C battery cells in response to the current excitation pulses;
the monitoring system further includes:
an impedance measurement module configured to cause the current generator to generate the current excitation pulses, receive the measured voltages, and estimate cell impedances of the C battery cells based on the current excitation pulses and the measured voltages; and
a temperature estimation module configured to estimate C temperatures of the C battery cells based on the estimated cell impedances.

6. The monitoring system of claim 5, wherein the temperature estimation module is further configured to generate the estimated temperatures of the C battery cells, further based on a state of charge (SOC) of the battery system and a frequency of the current excitation pulses.

7. The monitoring system of claim 1, wherein M is greater than one and wherein the battery management module is further configured to:
determine module residuals for each of the M battery modules;
calculate a standard deviation for the M battery modules based on the module residuals; and
selectively identify one of the M modules having an outlier module temperature by comparing the module residuals to the standard deviation.

8. The monitoring system of claim 7, wherein the battery management module calculates:
a first set of averages of the estimated temperatures of the C battery cells for corresponding ones of the M battery modules; and
a second average based on the first set of averages,
wherein the module residuals are based differences between the first set of averages and the second average.

9. The monitoring system of claim 7, wherein the battery management module calculates:
an average based on the sensed temperatures of the M battery modules; and
residuals for the M battery modules are calculated based a difference between the sensed temperatures of the M battery modules and the average.

10. The monitoring system of claim 1, wherein the battery management module is configured to adjust at least one operating parameter of an electric motor in response to determination that one of the C battery cells in one of the M battery modules has the cell outlier temperature.

11. The monitoring system of claim 10, wherein the at least one operating parameter includes performing a thermal runaway mitigation action in response to the cell outlier temperature being greater than a predetermined temperature threshold.

12. The monitoring system of claim 1, wherein the battery management module is configured switch between thermal control based a corresponding sensed temperature for the one of the M battery modules and the cell outlier temperature of the one of the C battery cells in one of the M battery modules.

13. A method for monitoring temperatures in a battery system, comprising:
generating sensed temperatures of M battery modules each including C battery cells using T temperature sensors, where T and M are integers greater than zero and C is an integer greater than one, and wherein T is greater than or equal to M and less than M times C;
performing battery impedance measurements on the C battery cells of the M battery modules;
generating estimated temperatures for each of the C battery cells of the M battery modules based on the battery impedance measurements;
selectively detecting at least one of the C battery cells having a cell outlier temperature based on the estimated temperatures of the C battery cells; and
altering at least one operating parameter of the battery system in response to the cell outlier temperature.

14. The method of claim 13, further comprising using the estimated temperatures of the C battery cells for the M battery modules and the sensed temperatures to selectively detect at least one of:
a fault in the T temperature sensors; and
one of the M battery modules having a module outlier temperature.

15. The method of claim 13, further comprising:
determining cell temperature residuals for each of the C battery cells of the M battery modules based on the battery impedance measurements for the C battery cells of the M battery modules;
calculating a first temperature standard deviation for each of the M battery modules based on the cell temperature residuals; and
selectively identifying one of the C battery cells having the cell outlier temperature by comparing the cell temperature residuals of the C battery cells to the first temperature standard deviation for corresponding ones of the M battery modules.

16. The method of claim 15, further comprising calculating the cell temperature residuals based on a difference between each of the estimated temperatures of the C battery cells for the M battery modules and an average of the estimated temperatures of the C battery cells for corresponding ones of the M battery modules.

17. The method of claim 16, further comprising:
generating current excitation pulses that are output to the C battery cells;
measuring voltages for the C battery cells in response to the current excitation pulses;
estimating cell impedances of the C battery cells based on the current excitation pulses and the measured voltages;
estimating C temperatures of the C battery cells based on the estimated cell impedances of the C battery cells, a state of charge (SOC) of the battery system and a frequency of the current excitation pulses;
determining module temperature residuals for each of the M battery modules;
calculating a module temperature standard deviation for the M battery modules based on the module temperature residuals; and
selectively identifying one of the M battery modules having an outlier module temperature by comparing the module temperature residuals to the module temperature standard deviation.

18. A non-transitory computer readable medium including instructions that, where executed by a processor, are configured to monitor temperatures in a battery system by:
receiving sensed temperatures of M battery modules each including C battery cells using T temperature sensors, where T and M are integers greater than zero and C is an integer greater than one, and wherein T is greater than or equal to M and less than M times C;
generating battery impedance measurements on the C battery cells of the M battery modules;
generating estimated temperatures for each of the C battery cells of the M battery modules based on the battery impedance measurements;
selectively detecting at least one of the C battery cells having a cell outlier temperature based on the estimated temperatures of the C battery cells; and
altering at least one operating parameter of the battery system in response to the cell outlier temperature.

19. The non-transitory computer readable medium of claim 18, further comprising instructions for using the estimated temperatures of the C battery cells for the M battery modules and the sensed temperatures to selectively detect at least one of:
a fault in one of the T temperature sensors; and
one of the M battery modules having a module outlier temperature.

20. The non-transitory computer readable medium of claim 18, further comprising instructions for:
determining cell temperature residuals for each of the C battery cells of the M battery modules based on the battery impedance measurements for the C battery cells of the M battery modules;
calculating a first temperature standard deviation for each of the M battery modules based on the cell temperature residuals; and
selectively identifying one of the C battery cells having the cell outlier temperature by comparing the cell temperature residuals of the C battery cells to the first temperature standard deviation for corresponding ones of the M battery modules.
